(19) United States
(12) Patent Application Publication
(10) Pub. No.: US 2026/0177634 A1
(43) Pub. Date: Jun. 25, 2026

(54) A NON-TRANSITORY COMPUTER READABLE MEDIUM STORING A PARAMETER ADAPTATION PROGRAM, PARAMETER ADAPTATION METHOD, AND PARAMETER ADAPTATION APPARATUS

(71) Applicant: TOYOTA BATTERY CO., LTD., Kosai-shi (JP)

(72) Inventor: Keita MATSUMOTO, Toyohashi-shi (JP)

(21) Appl. No.: 19/431,351

(22) Filed: Dec. 23, 2025

(30) Foreign Application Priority Data
Dec. 24, 2024 (JP) 2024-227538

(51) Int. Cl. G01R 31/392

(52) U.S. Cl. CPC G01R 31/392

(57) ABSTRACT

A parameter adaptation program performs: model configuration processing for defining a hysteresis voltage model in which an equivalent circuit is configured by a resistance parameter and a capacitance parameter; pulse response measurement processing for acquiring at least one voltage parameter from a measured value of a pulse voltage of a secondary battery; resistance parameter setting processing for calculating a value of the resistance parameter based on the at least one voltage parameter; and capacitance parameter optimization processing for acquiring a voltage response value by supplying a current signal equal to a pulse current to the hysteresis voltage model including the resistance parameter R calculated in the resistance parameter setting processing, and optimizing a value of the capacitance parameter in the hysteresis voltage model so that the voltage response value matches a value of the at least one voltage parameter acquired in the pulse response measurement processing.

### INCORPORATION BY REFERENCE

This application is based upon and claims the benefit of priority from Japanese patent application No. 2024-227538, filed on Dec. 24, 2024, the disclosure of which is incorporated herein in its entirety by reference for all purposes.

### BACKGROUND

The present disclosure relates to, for example, a parameter adaptation program, a parameter adaptation method, and a parameter adaptation apparatus which perform processing for adapting parameters of a hysteresis voltage model which estimates a hysteresis voltage generated during charging and discharging of a secondary battery.

A secondary battery has a hysteresis characteristic in which a difference occurs between a voltage at the start of rising and a voltage at the end of falling during charging or discharging. Further, in the control of a secondary battery, a state estimation model which estimates a state of charge and the like of the secondary battery from an internal state thereof is used. A hysteresis voltage model which estimates a hysteresis characteristic of the secondary battery is a part of the state estimation model. Examples of a technique for estimating parameters in the hysteresis voltage model are disclosed in Japanese Unexamined Patent Application Publication No. 2017-198542 and Japanese Unexamined Patent Application Publication No. 2019-185899.

The parameter estimation apparatus disclosed in Japanese Unexamined Patent Application Publication No. 2017-198542 is a battery parameter estimation apparatus which estimates parameters of an equivalent circuit model of a battery including an overvoltage model and a hysteresis model, in which a first current having a first amplitude and a second current having a second amplitude smaller than the first amplitude are input to the battery, the parameter related to the overvoltage model is estimated based on an output of the battery corresponding to the first current, and the parameter related to the hysteresis model is estimated based on an output of the battery corresponding to the second current.

The hysteresis voltage estimation apparatus disclosed in Japanese Unexamined Patent Application Publication No. 2019-185899 includes: a current measurement unit which measures a current flowing through a storage battery in which a plurality of stage structures are formed in the process of charging and discharging; a voltage measurement unit which measures a voltage between terminals of the storage battery; an SoC estimation unit which estimates an SoC of the storage battery from a current value measured by the current measurement unit or a voltage value measured by the voltage measurement unit; a mole fraction storage unit which stores a first group of variables that are mole fractions of electrode materials in the stages during charging of the storage battery and a second group of variables that are mole fractions of electrode materials in the stages during discharging of the storage battery; a transition probability calculation unit which calculates a first coefficient group of proportional coefficients representing individual transition probabilities during charging between the first group of variables and the second group of variables during charging and a second coefficient group of proportional coefficients representing individual transition probabilities during discharging between the first group of variables and the second group of variables during discharging from the current value, the first group of variables, and the second group of variables; a mole fraction calculation unit which calculates a new first group of variables and a new second group of variables at the current time from the first coefficient group or the second coefficient group in addition to the first group of variables and the second group of variables and stores the new first group of variables and the new second group of variables in the mole fraction storage unit; and a hysteresis voltage calculation unit which calculates a hysteresis voltage from a ratio between the sum of the new first group of variables and the sum of the new second group of variables and a voltage determined by using the SoC.

### SUMMARY

However, in the techniques disclosed in Japanese Unexamined Patent Application Publication No. 2017-198542 and Japanese Unexamined Patent Application Publication No. 2019-185899, there is a problem that it is necessary to use processing requiring high calculation performance, such as processing using a Kalman filter or processing using a mole fraction, in order to increase the accuracy of estimation of a hysteresis characteristic.

The present disclosure has been made in view of the above-described circumstances, and an object thereof is to perform processing for adapting parameters of a hysteresis voltage model with a small amount of calculation so that a hysteresis characteristic can be estimated with high accuracy.

An aspect of a parameter adaptation program according to the present disclosure is a parameter adaptation program for performing processing for adapting parameters configuring a hysteresis voltage model configured to estimate hysteresis of an output voltage, the hysteresis voltage model being connected in parallel with a state estimation model configured to estimate an internal state of a secondary battery, and the parameter adaptation program causing a computer to execute: model configuration processing for defining a hysteresis voltage model in which an equivalent circuit is configured by a resistance parameter and a capacitance parameter; pulse response measurement processing for acquiring at least one voltage parameter as an adaptation target from a measured value of a pulse voltage of the secondary battery obtained by applying a pulse current to the secondary battery; resistance parameter setting processing for calculating a value of the resistance parameter based on the at least one voltage parameter; and capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.

A parameter adaptation method according to the present disclosure is a parameter adaptation method for performing processing for adapting parameters configuring a hysteresis voltage model configured to estimate hysteresis of an output voltage, the hysteresis voltage model being connected in parallel with a state estimation model configured to estimate an internal state of a secondary battery, and the parameter adaptation method being automatically executed by a computer, in which the parameter adaptation method includes: model configuration processing for defining a hysteresis voltage model in which an equivalent circuit is configured by a resistance parameter and a capacitance parameter; pulse response measurement processing for acquiring at least one voltage parameter as an adaptation target from a measured value of a pulse voltage of the secondary battery obtained by applying a pulse current to the secondary battery; resistance parameter setting processing for calculating a value of the resistance parameter based on the at least one voltage parameter; and capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.

A parameter adaptation apparatus according to the present disclosure is a parameter adaptation apparatus configured to, in a control apparatus configured to control a secondary battery, perform processing for adapting parameters configuring a hysteresis voltage model configured to estimate hysteresis of an output voltage, the hysteresis voltage model being connected in parallel with a state estimation model configured to estimate an internal state of the secondary battery, and the parameter adaptation apparatus including: a memory; and an arithmetic unit configured to execute processing by using the memory, in which the arithmetic unit executes: model configuration processing for defining a hysteresis voltage model in which an equivalent circuit is configured by a resistance parameter and a capacitance parameter; pulse response measurement processing for acquiring at least one voltage parameter as an adaptation target from a measured value of a pulse voltage of the secondary battery obtained by applying a pulse current to the secondary battery; resistance parameter setting processing for calculating a value of the resistance parameter based on the at least one voltage parameter; and capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.

By the parameter adaptation program, the parameter adaptation method, and the parameter adaptation apparatus according to the present disclosure, it is possible to adapt parameters of a hysteresis voltage model in such a way that a hysteresis characteristic is estimated with high accuracy by using a preset current pulse and a simple calculation.

The above and other objects, features and advantages of the present disclosure will become more fully understood from the detailed description given hereinbelow and the accompanying drawings.

### BRIEF DESCRIPTION OF DRAWINGS

FIG. 1 is a flowchart for explaining a flow of parameter adaptation processing according to a first embodiment;

FIG. 2 is a diagram for explaining an example of a hysteresis voltage model according to the first embodiment;

FIG. 3 is a diagram showing an example of a measured value of a pulse response waveform according to the first embodiment; and

FIG. 4 is a diagram showing an example of a pulse response waveform calculated by the hysteresis voltage model according to the first embodiment.

### DESCRIPTION OF EMBODIMENTS

For the clarification of the description, the following descriptions and the drawings are partially omitted and simplified as appropriate. Further, elements described in the drawings as functional blocks which perform various types of processing may be configured as regards hardware by a Central Processing Unit (CPU), a memory, and other circuits, and are implemented as regards software by a program etc. loaded in the memory. Therefore, it will be understood by those skilled in the art that these functional blocks may be implemented in various forms such as hardware only, software only, or a combination thereof, and the present disclosure is not limited to any of them. Note that the same elements are denoted by the same reference numerals or symbols throughout the drawings, and redundant descriptions are omitted as necessary.

Further, the above-described program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a Random-Access Memory (RAM), a Read-Only Memory (ROM), a flash memory, a Solid-State Drive (SSD) or other types of memory technologies, a CD-ROM, a Digital Versatile Disc (DVD), a Blu-ray (Registered Trademark) disc or other types of optical disc storage, a magnetic cassette, a magnetic tape, and a magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

### First Embodiment

A parameter adaptation method for applying parameter adaptation processing according to a first embodiment is performed by executing a parameter adaptation program in a control apparatus (e.g., an Electric Control Unit (ECU)) which controls a secondary battery. This control apparatus is, for example, a computer including a memory and an arithmetic unit which performs various types of calculation processing by using the memory in accordance with a program. In other words, the control apparatus includes a parameter adaptation apparatus which executes the parameter adaptation processing described below. Further, the parameter adaptation processing according to the first embodiment is executed before starting an operation of the secondary battery. Furthermore, the parameter adaptation processing according to the first embodiment may be executed during the operation of the secondary battery as appropriate.

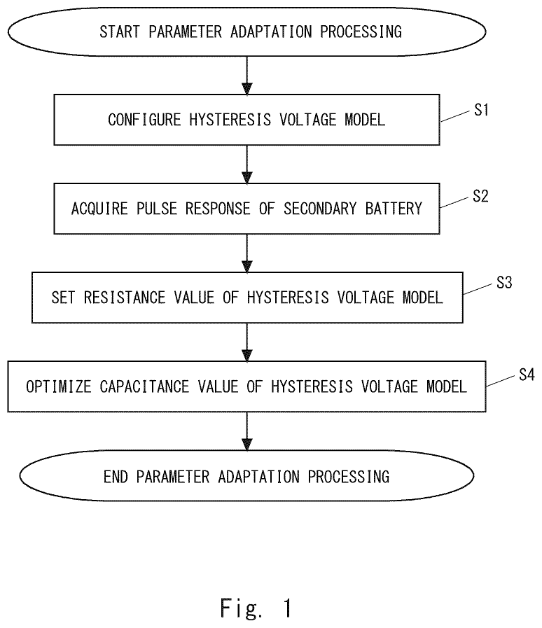

First, the parameter adaptation processing according to the first embodiment performs processing for adapting parameters configuring a hysteresis voltage model which estimates the hysteresis of an output voltage of a secondary battery. FIG. 1 is a flowchart for explaining a flow of the parameter adaptation processing according to the first embodiment.

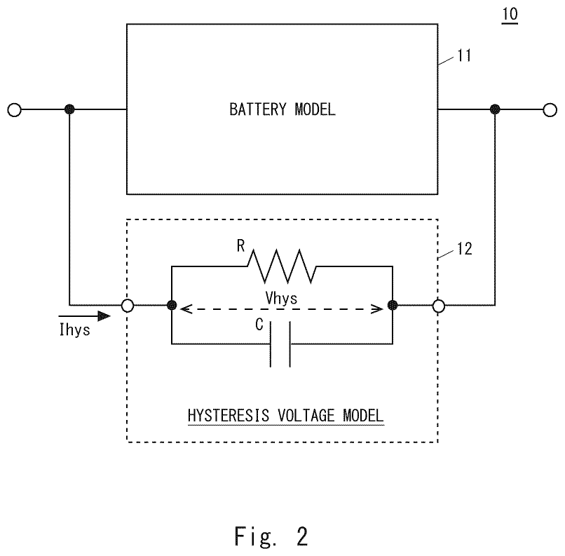

As shown in FIG. 1, in the parameter adaptation processing according to the first embodiment, first, model configuration processing for defining a hysteresis voltage model in which an equivalent circuit is configured by a resistance parameter and a capacitance parameter is performed (Step S1). Note that FIG. 2 is a diagram for explaining an example of the hysteresis voltage model according to the first embodiment.

As shown in FIG. 2, the hysteresis voltage model described below is one of numerical calculation models incorporated in a part of a state estimation model 10. The state estimation model 10 includes a battery model 11 and a hysteresis voltage model 12. The battery model 11 is a numerical calculation model which estimates an internal state, such as an electrochemical change, of an electrode of a secondary battery to be monitored by calculation.

Further, the secondary battery has a hysteresis characteristic in which a difference occurs in an output voltage of the secondary battery before and after a charging and discharging operation. This voltage difference may be referred to as a hysteresis voltage. The hysteresis voltage model 12 is a numerical calculation model which calculates a hysteresis voltage generated by the hysteresis characteristic. In the example shown in FIG. 2, the hysteresis voltage model 12 is connected in parallel with the battery model 11. Further, in the example shown in FIG. 2, the hysteresis voltage model 12 is expressed as an equivalent circuit in which a resistance parameter R and a capacitance parameter C are connected in parallel with each other. The hysteresis voltage model 12 is used to calculate a value of a hysteresis voltage Vhys when a current signal Ihys is supplied. Details of the current signal Ihys and the hysteresis voltage Vhys will be described later.

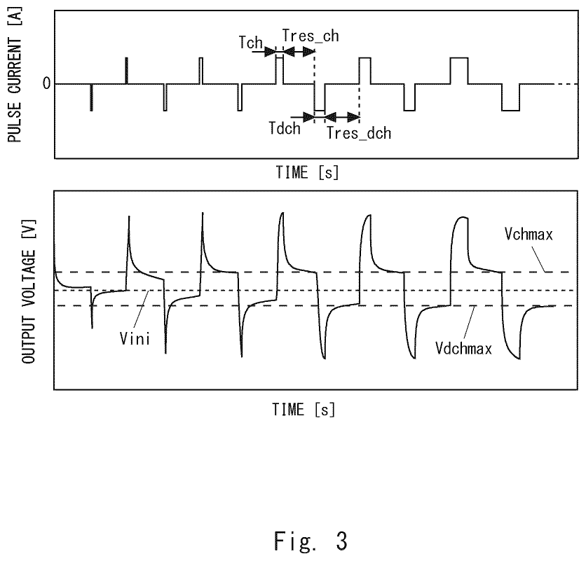

Referring to FIG. 1, in the parameter adaptation processing according to the first embodiment, pulse response measurement processing for acquiring at least one voltage parameter as an adaptation target from a measured value of a pulse voltage of a secondary battery obtained by applying a pulse current to the secondary battery is performed (Step S2). Note that FIG. 3 shows an example of a measured value of a pulse response waveform according to the first embodiment.

In the example shown in FIG. 3, an output voltage of the secondary battery is measured while changing the pulse width of a charging/discharging pulse current so that the pulse width increases with time. In the following description, a period of time during which a current value of a current pulse signal is zero is referred to as a rest period. Further, in the example shown in FIG. 3, the voltage parameters include an initial voltage Vini in a period of time during which the secondary battery is not charged or discharged, an output voltage after charging Vchmax which is an output voltage of the secondary battery at the time when a current zero period (hereinafter referred to as a rest period after charging Tres_ch) after the pulse current is in a state that simulates a charged state ends, and an output voltage after discharging Vdchmax which is an output voltage of the secondary battery at the time when a current zero period (hereinafter referred to as a rest period after discharging Tres_dch) after the pulse current is in a state that simulates a discharged state ends.

As shown in FIG. 3, in the secondary battery, when each of a pulse width Tch of a charging pulse current and a pulse width Tdch of a discharging pulse current reach a predetermined width or more, the output voltage after charging Vchmax of the secondary battery after the completion of charging and the output voltage after discharging Vdchmax of the secondary battery after the completion of discharging converge to substantially constant voltages. Note that the output voltage after charging Vchmax and the output voltage after discharging Vdchmax are voltages at the time when the rest period after charging Tres_ch and the rest period after discharging Tres_dch end after a charging pulse current or a discharging pulse current is applied. Further, in FIG. 3, an Open Circuit Voltage (OCV) of the secondary battery when sufficient time has elapsed after the completion of the charging and discharging operation is shown as the initial voltage Vini.

In the parameter adaptation processing according to the first embodiment, the values of the resistance parameter R and the capacitance parameter C of the hysteresis voltage model 12 are determined in such a way that the values of the output voltage after charging Vchmax and the output voltage after discharging Vdchmax in FIG. 3 can be calculated by numerical calculation. In the parameter adaptation processing according to the first embodiment, the value of the resistance parameter R is determined in Step S3 of FIG. 1, and the value of the capacitance parameter C is determined in Step S4 of FIG. 1.

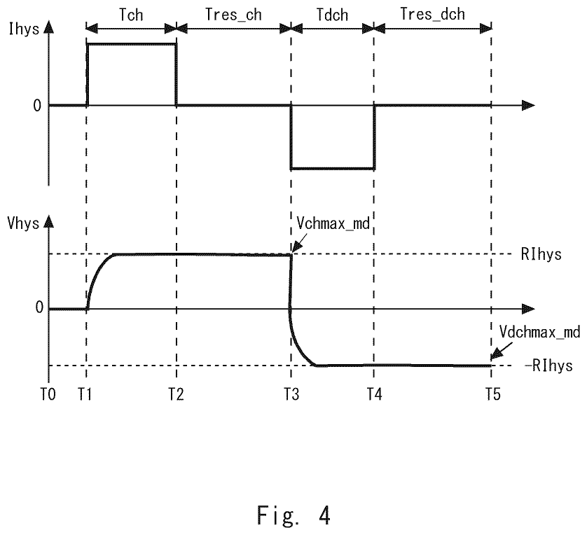

In Step S3, resistance parameter setting processing for calculating a value of the resistance parameter based on the voltage parameter (e.g., the output voltage after charging Vchmax and the output voltage after discharging Vdchmax) acquired in Step S2 is performed. Note that FIG. 4 shows an example of a pulse response waveform calculated by the hysteresis voltage model according to the first embodiment. FIG. 4 shows waveforms for one cycle of the charging/discharging cycle of the pulse current shown in FIG. 3 regarding the current signal Ihys and the hysteresis voltage Vhys of the hysteresis voltage model 12. As shown in FIG. 4, it is found that, when the current signal Ihys is supplied to the hysteresis voltage model 12, the voltage changes to a voltage determined by the resistance parameter R and the current signal Ihys, with a time constant determined by the resistance value of the resistance parameter R and the capacitance value of the capacitance parameter C.

Further, in the hysteresis voltage model 12, the capacitance parameter C is set to a capacitance value significantly larger than an estimated value of the capacitance parameter C determined in Step S4 in a period of time during which the current signal Ihys is less than a constant current value (e.g., 1 A). For example, it can be considered that the magnitude of the capacitance parameter C is set to about 1.0e12F in a period of time during which the current signal Ihys is less than a constant current value. Therefore, in the example shown in FIG. 4, the hysteresis voltage Vhys has a waveform that hardly changes in a period of time during which the current signal Ihys is less than a constant current value (e.g., a period of time during which the current signal Ihys is zero). Further, in resistance parameter calculation processing and capacitance parameter optimization processing according to the example shown in FIG. 4, an estimated output voltage after charging Vchmax_md corresponding to the output voltage after charging Vchmax and an estimated output voltage after discharging Vdchmax_md corresponding to the output voltage after discharging Vdchmax are calculated by using the hysteresis voltage model 12. The estimated output voltage after charging Vchmax_md is an output voltage value of the hysteresis voltage model 12 at the end of the rest period Tres_ch after the charging pulse period Tch of the current signal Ihys. The estimated output voltage after discharging Vdchmax_md is an output voltage value of the hysteresis voltage model 12 at the end of the rest period Tres_dch after the discharging pulse period Tdch of the current signal Ihys.

In the resistance parameter setting processing (Step S3), the resistance parameter R is determined so that the hysteresis voltage Vhys output by the hysteresis voltage model 12 when the current signal Ihys is supplied to the resistance parameter R matches the output voltage Vchmax and the output voltage Vdchmax shown in FIG. 3. For example, the resistance parameter R is calculated by the equation (1).

R={(Vchmax−Vini)+(Vini−Vdchmax)}/(2×I) (1)

In the equation (1), I is the magnitude of the current signal Ihys. When the current signal Ihys is 1.0 A, an average value of the difference between the output voltage after charging Vchmax and the initial voltage Vini and the difference between the initial voltage Vini and the output voltage after discharging Vdchmax is set as a value of the resistance parameter in the resistance parameter setting processing.

Next, the capacitance parameter optimization processing in Step S4 will be described in detail. In the capacitance parameter optimization processing, a voltage response value is acquired by supplying the current signal Ihys equal to the pulse current to the hysteresis voltage model 12 including the resistance parameter R whose value is determined in the resistance parameter setting processing (Step S3), and a value of the capacitance parameter C in the hysteresis voltage model 12 is optimized so that the voltage response value (e.g., the hysteresis voltage Vhys) matches a value of the voltage parameter (e.g., the output voltage after charging Vchmax and the output voltage after discharging Vdchmax) acquired in the pulse response measurement processing. More specifically, in the capacitance parameter optimization processing (Step S4), the estimated output voltage after charging Vchmax_md corresponding to the output voltage after charging Vchmax and the estimated output voltage after discharging Vdchmax_md corresponding to the output voltage after discharging Vdchmax are calculated by using the hysteresis voltage model. Further, in the capacitance parameter optimization processing (Step S4), while changing the capacitance parameter C in accordance with a predetermined rule, the capacitance parameter C in which the sum of the difference between the output voltage after charging Vchmax and the estimated output voltage after charging Vchmax_md and the difference between the output voltage after discharging Vdchmax and the estimated output voltage after discharging Vdchmax_md is minimized is searched for.

Conceivable examples of a method for searching for the above capacitance parameter C include a search method in which a capacitance value set in advance as the initial value of the capacitance parameter is used as a starting point, and the initial capacitance value is increased or decreased by ½ times, ¾ times, or ⅗ times while changing the variation width based on the rule of the bisection method, and a search method in which the initial capacitance value is increased or decreased by a predetermined step width.

In the hysteresis voltage model 12, the rise time and fall time of the hysteresis voltage Vhys in FIG. 4 are changed by changing the capacitance value. For example, if the capacitance value of the capacitance parameter C is large, the hysteresis voltage Vhys may not reach the estimated output voltage after charging Vchmax_md (or the estimated output voltage after discharging Vdchmax_md) during the charging pulse period Tch or the discharging pulse period Tdch. Therefore, in the capacitance parameter optimization processing, it may be preferable to set an initial capacitance value that is several times larger than the capacitance value assumed as the final value, and then set the capacitance parameter C to the largest capacitance value among the capacitance values at which the hysteresis voltage Vhys reaches the estimated output voltage after charging Vchmax_md (or the estimated output voltage after discharging Vdchmax_md) regardless of the length of the charging pulse period Tch and the discharging pulse period Tdch while gradually decreasing the capacitance value.

Note that, although the charging pulse width Tch and the discharging pulse width Tdch are widths of one type in FIG. 4, it becomes possible to set a capacitance value of the capacitance parameter C by which the hysteresis voltage model 12 can more accurately estimate the hysteresis voltage of the secondary battery by setting the pulse current and the current signal Ihys used in the measurement in Step S2 so as to include a plurality of pulse patterns having different pulse widths and pulse periods.

Further, when the pulse current and the current signal Ihys used in the measurement in Step S2 include a plurality of pulse patterns, the output voltage after charging and the output voltage after discharging as optimization targets are set for each pair of the pulse width and the pulse period, and the capacitance parameter C that minimizes the difference between the estimated output voltage after charging Vchmax_md and the estimated output voltage after discharging Vdchmax_md is calculated for each pair of the output voltage after charging and the output voltage after discharging.

As described above, by using the parameter adaptation processing according to the first embodiment, it is possible to obtain the hysteresis voltage model 12 which can estimate the hysteresis voltage with high accuracy by simple computation, without using processing requiring high calculation performance, such as processing using a Kalman filter or processing using a mole fraction.

Further, in the parameter adaptation processing according to the first embodiment, the parameters in the hysteresis voltage model 12 are determined in accordance with the hysteresis voltage characteristic known from the measured values with regard to the secondary battery. Therefore, a highly accurate hysteresis voltage model 12 can be configured even when a secondary battery whose internal parameters are unknown (e.g., an unidentified secondary battery) is used.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A non-transitory computer readable medium storing a parameter adaptation program for performing processing for adapting parameters configuring a hysteresis voltage model configured to estimate hysteresis of an output voltage, the hysteresis voltage model being connected in parallel with a state estimation model configured to estimate an internal state of a secondary battery, and the parameter adaptation program causing a computer to execute:
model configuration processing for defining the hysteresis voltage model in which an equivalent circuit is configured by a resistance parameter and a capacitance parameter;
pulse response measurement processing for acquiring at least one voltage parameter as an adaptation target from a measured value of a pulse voltage of the secondary battery obtained by applying a pulse current to the secondary battery;
resistance parameter setting processing for calculating a value of the resistance parameter based on the at least one voltage parameter; and
capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.

2. The non-transitory computer readable medium according to claim 1, wherein the pulse current includes a plurality of pulse patterns having different pulse widths and pulse periods.

3. The non-transitory computer readable medium according to claim 1, wherein the hysteresis voltage model is an equivalent circuit in which the resistance parameter and the capacitance parameter are connected in parallel with each other.

4. The non-transitory computer readable medium according to claim 1, wherein in the capacitance parameter optimization processing, a predetermined value is set as an initial value of the capacitance parameter.

5. The non-transitory computer readable medium according to claim 4, wherein when a current value indicated by the current signal is less than a specified value, the capacitance parameter has a fixed value at least 100 times greater than the value of the capacitance parameter set after the capacitance parameter optimization processing.

6. The non-transitory computer readable medium according to claim 1, wherein the voltage parameter includes: an initial voltage in a period of time during which the secondary battery is not charged or discharged; an output voltage after charging which is an output voltage of the secondary battery at a time when a current zero period after the pulse current reaches a state that simulates a charging state ends; and an output voltage after discharging which is an output voltage of the secondary battery at a time when a current zero period after the pulse current reaches a state that simulates a discharging state ends.

7. The non-transitory computer readable medium according to claim 6, wherein in the resistance parameter setting processing, a value obtained by dividing an average value of a difference between the output voltage after charging and the initial voltage and a difference between the initial voltage and the output voltage after discharging by a magnitude of the pulse current is set as the value of the resistance parameter.

8. The non-transitory computer readable medium according to claim 6, wherein, in the capacitance parameter optimization processing:
an estimated output voltage after charging corresponding to the output voltage after charging and an estimated output voltage after discharging corresponding to the output voltage after discharging are calculated by using the hysteresis voltage model, and
while changing the capacitance parameter in accordance with a predetermined rule, the capacitance parameter in which a sum of a difference between the output voltage after charging and the estimated output voltage after charging and a difference between the output voltage after discharging and the estimated output voltage after discharging is minimized.

9. A parameter adaptation method for performing processing for adapting parameters configuring a hysteresis voltage model configured to estimate hysteresis of an output voltage, the hysteresis voltage model being connected in parallel with a state estimation model configured to estimate an internal state of a secondary battery, and the parameter adaptation method being automatically executed by a computer, wherein the parameter adaptation method comprises:
model configuration processing for defining the hysteresis voltage model in which an equivalent circuit is configured by a resistance parameter and a capacitance parameter;
pulse response measurement processing for acquiring at least one voltage parameter as an adaptation target from a measured value of a pulse voltage of the secondary battery obtained by applying a pulse current to the secondary battery;
resistance parameter setting processing for calculating a value of the resistance parameter based on the at least one voltage parameter; and
capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.

10. A parameter adaptation apparatus configured to, in a control apparatus configured to control a secondary battery, perform processing for adapting parameters configuring a hysteresis voltage model configured to estimate hysteresis of an output voltage, the hysteresis voltage model being connected in parallel with a state estimation model configured to estimate an internal state of the secondary battery, and the parameter adaptation apparatus comprising:
a memory; and
an arithmetic unit configured to execute processing by using the memory,
wherein the arithmetic unit executes:
model configuration processing for defining the hysteresis voltage model in which an equivalent circuit is configured by a resistance parameter and a capacitance parameter;
pulse response measurement processing for acquiring at least one voltage parameter as an adaptation target from a measured value of a pulse voltage of the secondary battery obtained by applying a pulse current to the secondary battery;
resistance parameter setting processing for calculating a value of the resistance parameter based on the at least one voltage parameter; and
capacitance parameter optimization processing for acquiring a voltage response value by supplying a current signal equal to the pulse current to the hysteresis voltage model including the resistance parameter whose value is determined in the resistance parameter setting processing, and optimizing a value of the capacitance parameter in the hysteresis voltage model so that the voltage response value matches a value of the at least one voltage parameter acquired in the pulse response measurement processing.
